(19) United States
(12) Patent Application Publication
(10) Pub. No.: US 2025/0329550 A1
(43) Pub. Date: Oct. 23, 2025

(54) PANEL-LEVEL PACKAGING METHOD FOR SEMICONDUCTOR STRUCTURE

(71) Applicant: SiPLP Microelectronics (Chongqing) Limited, Chongqing (CN)

(72) Inventor: Wenwu ZHOU, Chongqing (CN)

(73) Assignee: SiPLP Microelectronics (Chongqing) Limited, Chongqing (CN)

(21) Appl. No.: 18/870,021

(22) PCT Filed: Apr. 17, 2023
(86) PCT No.: PCT/CN2023/088641

§ 371 Date: Nov. 27, 2024

(30) Foreign Application Priority Data
Jun. 1, 2022 (CN) 202210621978.4

(51) Int. Cl. H01L 21/56; H01L 21/78; H01L 23/00

(52) U.S. Cl. CPC H01L 21/561; H01L 21/78; H01L 24/94; H01L 2224/94

(57) ABSTRACT

Provided in the present invention is a panel-level packaging method, comprising: providing a plurality of wafers, a hollowed-out panel and a first carrier panel, the hollowed-out panel being provided with a plurality of hollowed-out positions, the size of the hollowed-out positions being slightly larger than that of the wafers, the hollowed-out panel being surface-mounted onto the first carrier panel, front faces of the wafers being provided with a plurality of first welding pads, and the wafers being aimed at the hollowed-out positions and being surface-mounted onto the first carrier panel; forming a first encapsulation layer which at least covers side faces of the wafers; removing the first carrier panel to obtain a first encapsulation structure, and surface-mounting the first encapsulation structure onto a second carrier panel; forming an electrically conductive structure to obtain a semiconductor intermediate structure; and cutting the semiconductor intermediate structure to obtain a plurality of sub-structures.

### CROSS-REFERENCE TO RELATED APPLICATIONS

The present application claims priority to Chinese patent application No. 202210621978.4, filed with the China National Intellectual Property Administration on Jun. 1, 2022, entitled “Panel-level packaging method for semiconductor structure”, which is hereby incorporated by reference in its entirety.

### TECHNICAL FIELD

The present disclosure relates to the technical field of semiconductors, and in particular, to a panel-level packaging method of a semiconductor structure.

### BACKGROUND

In existing packaging technologies, in a process of performing panel-level fan-out packaging processing on chips, in order to improve processing precision, a redistribution structure needs to be formed on a wafer by using a wafer-level packaging device first, so as to widen a distance between adjacent pads for the chips, then the wafer is cut to obtain a plurality of chips, and then the chips are mounted on a panel-level carrier board and fan-out packaging is performed by using a panel-level packaging device.

That is, in prior arts, in order to improve processing precision, both a panel-level device and a wafer-level device need to be used, resulting in high packaging cost.

### SUMMARY

A purpose of the present disclosure is to provide a panel-level packaging method for a semiconductor structure, which can realize wafer-level packaging only with panel-level equipment and reduce cost.

In order to achieve the above purpose and other related purposes, the present disclosure provides a panel-level packaging method for a semiconductor structure, including:
providing wafers, a hollowed plate and a first carrier, where the hollowed plate includes hollowed portions, a size of each of the hollowed portions is larger than a size of each of the wafers, the hollowed plate is attached to the first carrier, a front surface of the wafer is provided with first pads, the wafers are aligned to the hollowed portions and are attached to the first carrier, and the first pads face toward the first carrier;
forming a first encapsulation layer, where the first encapsulation layer covers side surfaces of the wafers;
removing the first carrier to obtain a first encapsulation structure, and attaching the first encapsulation structure on a second carrier, where the first pads face away from the second carrier;
forming a conductive structure in contact with the first pads to obtain a semiconductor intermediate structure; and
cutting the semiconductor intermediate structure to obtain sub-structures.

Optionally, in the panel-level packaging method of the semiconductor structure, a size of each hollowed portion is 1 mm to 5 mm larger than a size of the wafer.

Optionally, in the panel-level packaging method for the semiconductor structure, the conductive structure includes a pillar layer, the pillar layer includes first lead-out metal pads and first conductive pillars, and forming the pillar layer includes:
forming the first lead-out metal pads, where each of the first lead-out metal pads is in contact with a surface of one of the first pads facing away from the second carrier;
forming the first conductive pillars, where each of the first conductive pillars is in contact with a surface of one of the first lead-out metal pads facing away from the second carrier.

Optionally, in the panel-level packaging method for the semiconductor structure, after forming the first conductive pillars, where each of the first conductive pillars is in contact with the surface of one of the first lead-out metal pads facing away from the second carrier, forming the pillar layer further includes:
forming a second insulating layer covering the first lead-out metal pads, the first conductive pillars and an exposed front surface of the wafer; and
removing a portion of the second insulating layer to expose surfaces of the first conductive pillars facing away from the second carrier.

Optionally, in the panel-level packaging method for the semiconductor structure, after removing the portion of the second insulating layer to expose the surfaces of the first conductive pillars facing away from the second carrier, the panel-level packaging method further includes: removing the second carrier and the hollowed plate to obtain the semiconductor intermediate structure.

In the panel-level packaging method for the semiconductor structure, where the conductive structure further includes a second redistribution structure, the second redistribution structure includes first conductive traces and second conductive pillars, and forming the second redistribution structure includes:
forming the first conductive traces, where each of the first conductive traces is in contact with one of the first conductive pillars;
forming the second conductive pillars, where each of the second conductive pillars is in contact with a surface of one of the first conductive traces facing away from the second carrier.

Optionally, in the panel-level packaging method for the semiconductor structure, after forming the second conductive pillars, where each of the second conductive pillars is in contact with the surface of one of the first conductive traces facing away from the second carrier, forming the second redistribution structure further includes:
forming a fourth insulating layer covering the first conductive traces and the second conductive pillars; and
removing a portion of the fourth insulating layer to expose the second conductive pillars.

Optionally, in the panel-level packaging method for the semiconductor structure, after removing the portion of the fourth insulating layer to expose the second conductive pillars, the panel-level packaging method further includes: removing the second carrier and the hollowed plate to obtain the semiconductor intermediate structure.

Optionally, in the panel-level packaging method for the semiconductor structure, after cutting the semiconductor intermediate structure to obtain the sub-structures, the panel-level packaging method for the semiconductor structure further includes:
providing a third carrier and selecting some of the sub-structures, where the conductive structure is located in a front surface of each of the selected sub-structures, the selected sub-structures are attached on the third carrier, and the conductive structure faces toward the third carrier;
forming a second encapsulation layer covering the selected sub-structures;
removing the third carrier to obtain a second encapsulation structure, and attaching the second encapsulation structure on a fourth carrier, where the conductive structure faces away from the fourth carrier; and
forming a fourth redistribution structure in contact with the conductive structure to obtain a semiconductor package structure, and cutting the semiconductor package structure to obtain sub-package structures.

Optionally, in the panel-level packaging method for the semiconductor structure, where the fourth redistribution structure includes third conductive traces, third conductive pillars, and third solder balls, and forming the fourth redistribution structure includes:
forming the third conductive traces, where each of the third conductive traces is in contact with the conductive structure;
forming the third conductive pillars, where each of the third conductive pillars is in contact with a surface of one of the third conductive traces facing away from the fourth carrier;
forming a fifth insulating layer covering the third conductive traces, the third conductive pillars, and front surfaces of the selected sub-structures;
removing a portion of the fifth insulating layer to expose the third conductive pillars; and
forming the third solder balls, where each of the third solder balls is in contact with a surface of one of the third conductive pillars facing away from the fourth carrier.

Optionally, in the panel-level packaging method for the semiconductor structure, where the conductive structure further includes a third redistribution structure, the third redistribution structure includes second conductive traces, third pads and second solder balls, and forming the third redistribution structure includes:
forming the second conductive traces, where each of the second conductive traces is in contact with one of the first conductive pillars;
forming a third insulating layer covering the second insulating layer and the second conductive traces;
forming second openings, where the second openings penetrate through the third insulating layer, and each of the second openings exposes one of the second conductive traces;
forming the third pads, where each of the third pads is in contact with one of the second conductive traces; and
forming the second solder balls, where each of the second solder balls is in contact with a surface of one of the third pads facing away from the second carrier to obtain the semiconductor intermediate structure.

Optionally, in the panel-level packaging method for the semiconductor structure, the conductive structure includes a first redistribution structure, the first redistribution structure includes second lead-out metal pads, second pads and first solder balls, and forming the first redistribution structure includes:
forming the second lead-out metal pads, where each of the second lead-out metal pads is in contact with a surface of one of the first pads facing away from the second carrier;
forming a first insulating layer covering the second lead-out metal pads and an exposed front surface of the wafer;
forming first openings, where the first openings penetrate through the first insulating layer, and each of the first openings exposes one of the second lead-out metal pads;
forming the second pads, where each of the second pads is filled in one of the first openings, so that the second pads are in contact with the second lead-out metal pads; and
forming the first solder balls, where each of the first solder balls is in contact with a surface of one of the second pads facing away from the second carrier to obtain the semiconductor intermediate structure.

Compared with prior arts, the technical solution of the present disclosure has following beneficial effects.

In the present disclosure, by using the hollowed-out panel, the wafers can be reconstructed and encapsulated as panel-level, and panel-level packaging is performed to realize wafer-level packaging, that is, the present disclosure realizes wafer-level packaging by using only the panel-level equipment, which can meet the precision requirement, reduce cost, and avoid a problem of wafer cracking caused by stress in the encapsulation process.

### BRIEF DESCRIPTION OF DRAWINGS

FIG. 1 is a schematic diagram of a structure after attaching chips.

FIG. 2 is a schematic diagram of a structure after encapsulating chips from a view.

FIG. 3 is a schematic diagram of a structure after encapsulating chips from another view.

FIG. 4 is a schematic structural diagram of a wafer.

FIG. 5 is a schematic structural diagram of a chip surface formed with chip metal pads and a passivation layer from a view.

FIG. 6 is a schematic structural diagram of a chip surface formed with chip metal pads and a passivation layer from another view.

FIG. 7 is a schematic diagram of a structure after forming a first insulating layer from a view.

FIG. 8 is a schematic diagram of a structure after forming a first insulating layer from another view.

FIG. 9 to FIG. 14 are schematic structural diagrams of forming a conductive structure.

FIG. 15 is a flowchart of a panel-level packaging method of a semiconductor structure according to an embodiment of the present disclosure.

FIG. 16 is a perspective diagram of a structure after attaching a hollowed plate according to an embodiment of the present disclosure.

FIG. 17 is a diagram of a structure after attaching a hollowed plate according to an embodiment of the present disclosure.

FIG. 18 is a perspective diagram of a structure after attaching wafers according to an embodiment of the present disclosure.

FIG. 19 is a diagram of a structure after attaching wafers according to an embodiment of the present disclosure.

FIG. 20 is a perspective diagram of a structure after forming a first encapsulation layer according to an embodiment of the present disclosure.

FIG. 21 is a diagram of a structure after forming a first encapsulation layer according to an embodiment of the present disclosure.

FIG. 22 is a perspective diagram of a structure after grinding a first encapsulation layer according to an embodiment of the present disclosure.

FIG. 23 is a diagram of a structure after grinding a first encapsulation layer according to an embodiment of the present disclosure.

FIG. 24 is a perspective diagram of a structure after attaching first encapsulation structures according to an embodiment of the present disclosure.

FIG. 25 is a diagram of a structure after attaching first encapsulation structures according to an embodiment of the present disclosure.

FIG. 26 is an enlarged view of a partial area A in FIG. 25.

FIG. 27 is a diagram of a structure after forming second lead-out metal pads according to an embodiment of the present disclosure.

FIG. 28 is a diagram of a structure after forming a first insulating layer according to an embodiment of the present disclosure.

FIG. 29 is a diagram of a structure after forming first openings according to an embodiment of the present disclosure.

FIG. 30 is a diagram of a structure after forming second pads according to an embodiment of the present disclosure.

FIG. 31 is a diagram of a structure after forming a first protective resin film according to an embodiment of the present disclosure.

FIG. 32 is a diagram of a structure after forming first solder balls according to an embodiment of the present disclosure.

FIG. 33 is a diagram of a structure after forming first conductive pillars according to an embodiment of the present disclosure.

FIG. 34 is a diagram of a structure after forming a second insulating layer according to an embodiment of the present disclosure.

FIG. 35 is a diagram of a structure after a ground second insulating layer according to an embodiment of the present disclosure.

FIG. 36 is a diagram of a structure after forming first conductive traces according to an embodiment of the present disclosure.

FIG. 37 is a diagram of a structure after forming second conductive pillars according to an embodiment of the present disclosure.

FIG. 38 is a diagram of a structure after forming a fourth insulating layer according to an embodiment of the present disclosure.

FIG. 39 is a diagram of a structure after forming second openings according to an embodiment of the present disclosure.

FIG. 40 is a diagram of a structure after forming third pads according to an embodiment of the present disclosure.

FIG. 41 is a diagram of a structure after forming a second protective resin film according to an embodiment of the present disclosure.

FIG. 42 is a diagram of a structure after forming second solder balls according to an embodiment of the present disclosure.

FIG. 43 and FIG. 44 are diagrams of structures after attached sub-structures according to an embodiment of the present disclosure.

FIG. 45 and FIG. 46 are diagrams of structures after forming a second encapsulation layer according to an embodiment of the present disclosure.

FIG. 47 and FIG. 48 are diagrams of structures after attached second encapsulation structures according to an embodiment of the present disclosure.

FIG. 49 and FIG. 50 are diagrams of structures after forming third conductive pillars according to an embodiment of the present disclosure.

FIG. 51 and FIG. 52 are diagrams of structures after forming a fifth insulating layer according to an embodiment of the present disclosure.

FIG. 53 and FIG. 54 are diagrams of structures after forming third solder balls according to an embodiment of the present disclosure.

### DETAILED DESCRIPTION

The panel-level packaging method for a semiconductor structure provided by the present disclosure will be further described in detail below with reference to the accompanying drawings and specific embodiments. The advantages and features of the present disclosure will become more apparent from the following description. It should be noted that, the drawings are all in a very simplified form and are all in imprecise proportions, which are only used to facilitate and clearly describe the purpose of the embodiments of the present disclosure.

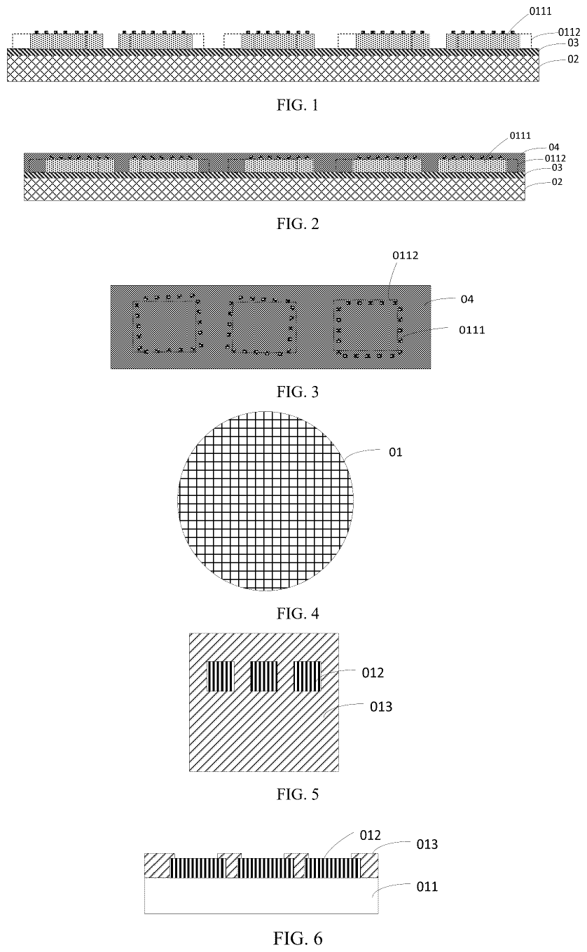

Generally, the panel-level fan-out packaging process requires panel-level reconstruction, where problems such as position deviation will arise after chips are attached and encapsulation is reconstructed, resulting in reduction of processing precision capability, as shown in FIGS. 1-3. FIG. 1 shows a schematic diagram of a structure after attaching chips, the chips are attached on a carrier 02, an adhesive layer 03 is formed between the chips and the carrier 02, and actual positions 0111 of the chips on the carrier 02 deviate from theoretical positions 0112 of the chips on the carrier 02. FIG. 2 and FIG. 3 show schematic diagrams of a structure in which chips have been encapsulated, that is, the chips are encapsulated to form an encapsulation layer 04. It can be found that the encapsulated chips also suffer from position deviation.

However, quite a number of chips require fairly high processing precision, and the precision requirement cannot be achieved simply by using the panel-level packaging technology, it is therefore necessary to use wafer-level packaging technology to first perform redistribution on a wafer, widen corresponding distance between wirings and between pads, and then perform panel-level reconstruction to achieve fan-out packaging.

FIG. 4 to FIG. 14 show a process of redistribution on a wafer by using a wafer-level packaging technology, and the wafer-level packaging processing technical solution specifically includes following steps.
Step S01: providing a wafer 01, where the wafer 01 includes a plurality of chips 011, and a plurality of chip metal pads 012 and a chip passivation layer 013 partially covering the chip metal pads 012 are formed on a surface of each chip 011.
Step S02: coating a first insulating layer 051 on a surface of the wafer 01, and opening the first insulating layer 051 at the position of the chip metal pads 012 to form first openings 0511 to expose a part of each chip metal pad 012.
Step S03: forming conductive traces 061 on the first insulating layer 051, where the conductive traces 061 further fill the first openings 0511, so that the conductive traces 061 are in contact with the chip metal pads 012.
Step S04: forming a second insulating layer 052 on the conductive traces 061, and opening the second insulating layer 052 to form second openings 0521 to expose a part of each conductive trace 061.
Step S05: forming pads 062 in the second openings 0521, where the pads 062 are in contact with the conductive traces 061 to obtain a wafer-level package structure.
Step S06: performing panel-level fan-out packaging on the wafer-level package structure.

Referring to FIGS. 4-6, step S01 is performed to provide a wafer 01. The wafer 01 may include a plurality of chips 011, and a plurality of chip metal pads 012 and a chip passivation layer 013 partially covering the chip metal pads 012 are formed on a surface of each chip 011.

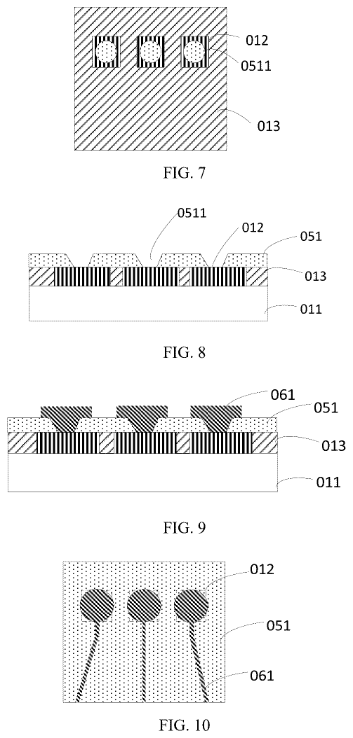

Referring to FIGS. 7-8, step S02 is performed to coat a first insulating layer 051 on a surface of the wafer 01, and open the first insulating layer 051 to form a plurality of first openings 0511 exposing a part of each chip metal pad 012. That is, a window is opened on each chip metal pad 012 to form a first opening 0511.

Referring to FIGS. 9-14, a redistribution structure is formed on the first insulating layer 051, and the redistribution structure includes conductive traces 061 and pads 062 in contact with the conductive traces 061. Formation process of the redistribution structure includes steps S03, S04 and S05.

Referring to FIGS. 9-10, step S03 is performed to form conductive traces 061 on the first insulating layer 051, and the conductive traces 061 are in contact with the chip metal pads 012.

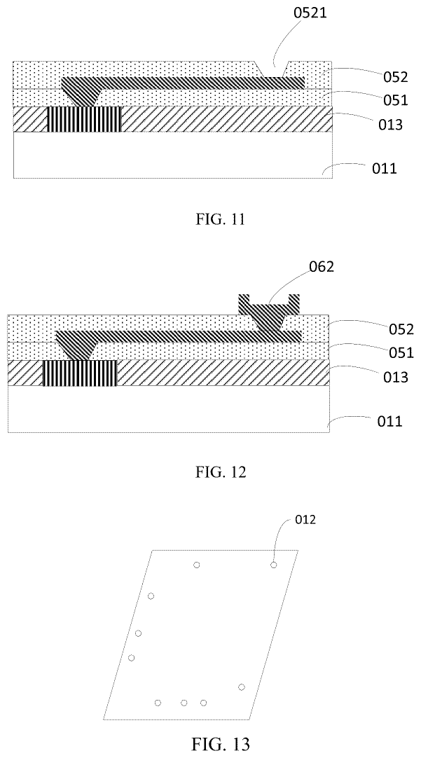

Referring to FIG. 11, step S04 is performed to form a second insulating layer 052 on the conductive traces 061, and open the second insulating layer 052 to form a plurality of second openings 0521, that is, windows are opened at positions of the conductive traces to form second openings 0521, and positions of the second openings 0521 deviate from positions corresponding to the first openings 0511.

Referring to FIG. 12, step S05 is performed to form pads 062 in the second openings 0521, and the pads 062 are in contact with the conductive traces 061. Steps S02 to S05 are all completed in the wafer-level device.

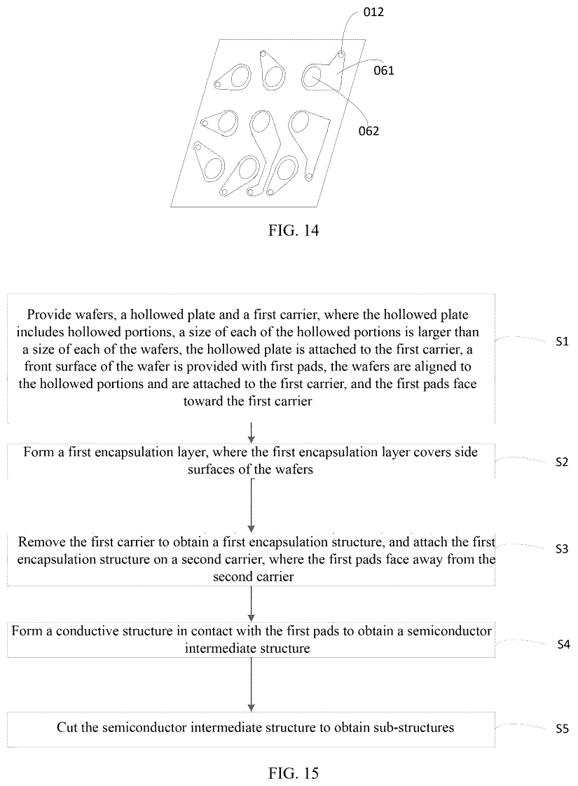

Referring to FIG. 13 to FIG. 14, after the Al soldering area (i.e., the chip metal pad 012) and the new soldering area (i.e., the pad 062) are connected through the conductive traces 061 to rearrange and increase the distance between soldering areas, the precision requirements of subsequent processing can be reduced.

Therefore, in order to meet the processing precision requirement, the packaging of a common semiconductor structure needs to adopt wafer-level processing equipment and panel-level packaging equipment, that is, the wafer-level processing equipment is adopted for wafer-level packaging processing, and the panel-level packaging equipment is adopted for panel-level fan-out packaging processing, but these equipment are costly. If the package structure of the wafer-level packaging equipment is achieved by the panel-level packaging equipment, a wafer needs to be manufactured into a panel with a size corresponding to the panel-level packaging, and due to characteristic of the wafer, the wafer is very easy to crack when being manufactured into the panel. In addition, when fan-out packaging is performed, and when the wafer includes aluminum pads, that is, a material of the chip metal pads is aluminum, a metal protective layer needs to be made for the wafer aluminum pads to avoid oxidation of the aluminum pads, and a conventional method is to chemically plate a layer of metal (generally nickel and gold) to protect the aluminum pads, which can avoid a problem of excessive resistance, but is relatively high in cost. Moreover, the conventional method cannot completely avoid a problem of damage to the aluminum pads caused by a laser opening process. In addition, in existing panel-level processing manners, wiring is usually led out by openings, and residual adhesive cannot be removed by grinding since grinding may cause block of openings.

The present disclosure provides a panel-level packaging method for a semiconductor structure, which adopts a hollowed plate to encapsulate and reconstruct a wafer into panel-level, and then perform panel-level packaging to realize wafer-level packaging, so as to expand a processing range of the panel-level packaging equipment. According to the present disclosure, wafer-level packaging can be realized by adopting a panel-level packaging equipment, and in a condition of high precision requirement, the present disclosure can realize, by adopting the panel-level packaging technology, the redistribution that needs to be performed directly on the wafer and then the panel-level packaging to meet such precision requirement, thus the present disclosure adopts the panel-level device to perform wafer-level packaging processing without using the wafer-level processing device, which is less costly.

According to the present disclosure, before the wafer with aluminum pads is subjected to panel-level packaging, the panel-level equipment can process a layer of protective metal on the aluminum pads, so that a problem of overhigh resistance caused by aluminum pad oxidation is avoided. In addition, the panel-level packaging method for the semiconductor structure can solve a problem of scrapping caused by residual adhesive and the like in the processing process.

Referring to FIG. 15, a panel-level packaging method for a semiconductor structure of the present disclosure includes following steps.
Step S1: providing wafers, a hollowed plate and a first carrier, where the hollowed plate includes hollowed portions, a size of each of the hollowed portions is larger than a size of each of the wafers, the hollowed plate is attached to the first carrier, a front surface of the wafer is provided with first pads, the wafers are aligned to the hollowed portions and are attached to the first carrier, and the first pads face toward the first carrier.
Step S2: forming a first encapsulation layer, where the first encapsulation layer covers side surfaces of the wafers.
Step S3: removing the first carrier to obtain a first encapsulation structure, and attaching the first encapsulation structure on a second carrier, where the first pads face away from the second carrier.
Step S4: forming a conductive structure in contact with the first pads to obtain a semiconductor intermediate structure.
Step S5: cutting the semiconductor intermediate structure to obtain sub-structures.

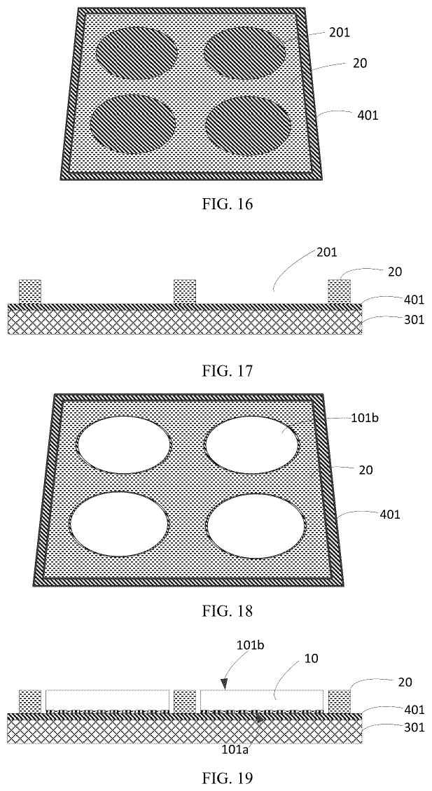

Referring to FIGS. 16-19, step S1 is performed to provide wafers 10, a hollowed plate 20 and a first carrier 301, and the hollowed plate 20 is first attached on the first carrier 301, then the wafers 10 are aligned to the hollowed portions 201 on the hollowed plate 20, and the aligned wafers 10 are also attached on the first carrier 301. In this embodiment, the hollowed plate 20 and the wafers 10 may be fixed on the first carrier 301 by pressing or by adhesive. For example, adhesive may be disposed between the first carrier 301 and the wafers 10 and between the first carrier 301 and the hollowed plate 20, so as to fix them. Specifically, a surface of the first carrier 301 may be fully coated with adhesive, and the hollowed plate 20 and the wafers 10 are placed on the adhesive. The adhesive may be made of a material easy to peel, so as to peel the first carrier 301 from the hollowed plate 20 and the wafers 10, for example, a releasable double-sided tape. For example, in FIGS. 16 and 17, the hollowed plate 20 is fixed on the first carrier 301 by adhesive (i.e., a first adhesive layer 401); and in FIGS. 18 and 19, the wafers 10 are fixed on the first carrier 301 by adhesive (i.e., the first adhesive layer 401).

In an embodiment, the wafer 10 includes a circular structure. A front surface 101a of each wafer 10 is provided with a plurality of first pads 1011, specifically, the wafer 10 includes a plurality of chips connected to each other, and a front surface of each chip is provided with a plurality of first pads 1011. The chips being connected to each other means that at least part of layers of the chips are of an integrated structure. The first pad 1011 is preferably made of aluminum. In this embodiment, the first pads 1011 attached on the front surface of the wafer on the first carrier 301 face toward the first carrier 301.

The hollowed plate 20 is preferably an encapsulated hollowed plate, and further, a material of the hollowed plate 20 is preferably same as a material used for the first encapsulation layer, so as to achieve matching of material characteristics, reduce stress borne by the wafer after encapsulation, and prevent the wafer from being broken after the first encapsulation layer is formed. That is, the hollowed plate 20 may be a polymer, a resin, a resin composite material or a polymer composite material. The hollowed plate 20 is provided with a plurality of hollowed portions, for example, four hollowed portions 201 are provided on the hollowed plate 20 as shown in FIG. 16. A size of the hollowed portion 201 needs to be slightly larger than that of the wafer 10, and further, the size of the hollowed portion 201 is about 1 mm to 5 mm larger than that of the wafer.

The first carrier 301 is preferably a panel-level carrier, and the panel-level carrier refers to a large carrier used in a panel-level packaging process.

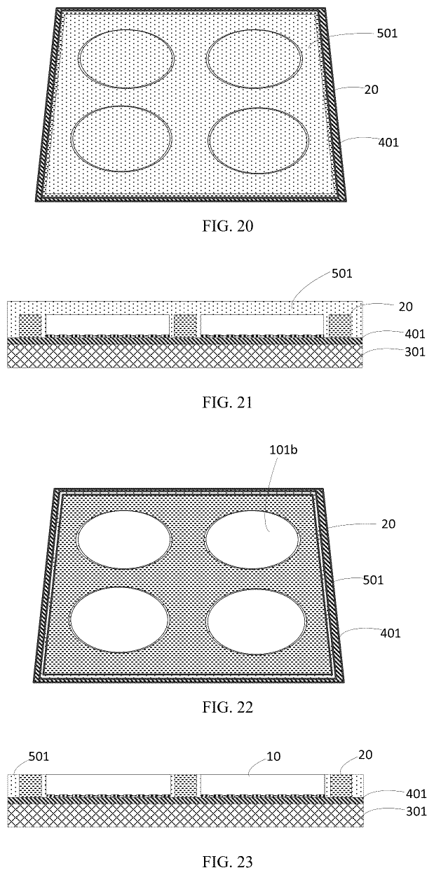

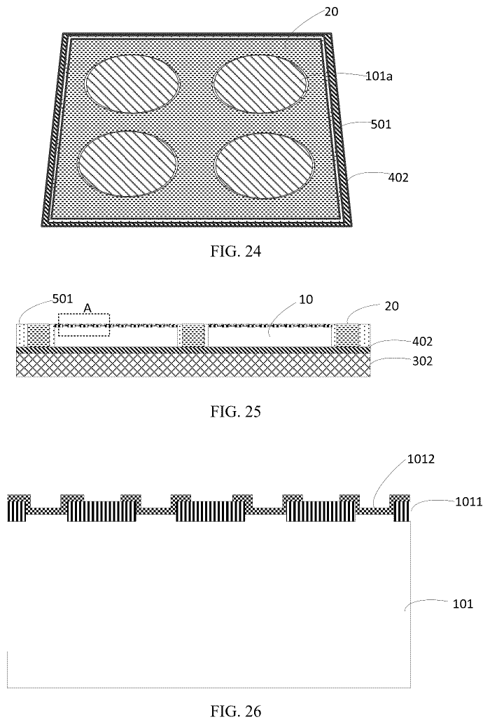

Referring to FIGS. 20-23, step S2 is performed to encapsulate the wafers 10 to form the first encapsulation layer 501, where the first encapsulation layer 501 at least covers side surfaces of the wafers 10. Further, the first encapsulation layer 501 fills a gap between the wafers 10 and the hollowed plate 20 at the hollowed portions 201. As shown in FIGS. 22 and 23, the first encapsulation layer 501 only covers side surfaces of the wafers 10. In other embodiments, the first encapsulation layer 501 covers side surfaces of the wafers 10 and back surfaces 101b of the wafers 10. In this embodiment, the first encapsulation layer 501 further covers the hollowed plate 20, and further, the first encapsulation layer 501 preferably covers side surfaces of the hollowed plate 20, which helps to improve strength of the entire plate in subsequent processes.

Referring to FIGS. 20-FIG. 23, a specific manner when the first encapsulation layer 501 covers only side surface of the wafers 10 includes:
Step S21: forming a first encapsulation material layer on back surfaces 101b of the wafer, the hollowed plate 20 and an exposed part of the first carrier 301;
Step S22: grinding the first encapsulation material layer until the back surfaces 101b of the wafers are exposed to form the first encapsulation layer 501.

Referring to FIG. 20 to FIG. 21, step S21 is performed to form the first encapsulation material layer on the back surfaces 101b of the wafers, the hollowed plate 20 and the exposed part of the first carrier 301. The first encapsulation material layer preferably includes a material with a small shrinkage rate and a small CTE (coefficient of thermal expansion), and the material needs to be capable of subsequent RDL (redistribution layer) processing, and further needs to have a certain acid and alkali resistance. Further, the first encapsulation material layer may be a polymer, a resin, a resin composite material or a polymer composite material. For example, the first encapsulation material layer may be a resin with a filler, where the filler includes inorganic particles. The first encapsulation material layer may be formed by lamination, injection molding, compression molding or transfer molding.

Referring to FIGS. 22-23, step S22 is performed to grind the first encapsulation material layer until back surfaces of the wafers 10 are exposed to form the first encapsulation layer 501. Grinding can reduce a stress caused by a difference between thermal expansion ratios of the encapsulation material and the wafer 10, and the occurrence of wafer 10 cracking can be reduced.

In other embodiments, when the first encapsulation layer covers the side surfaces of the wafers 10 and the back surfaces of the wafers 10, only step S21 needs to be performed, and the obtained first encapsulation material layer is the first encapsulation layer 501.

Referring to FIGS. 24-25, step S3 is performed to remove the first carrier 301 to obtain a first encapsulation structure, and attach the first encapsulation structure to a second carrier 302, where the first pads 1011 face away from the second carrier 302. Removing manners of the first carrier 301 may be an existing removing manner such as laser peel-off, which will not be specified herein. The second carrier 302 is preferably a panel-level carrier. In this embodiment, the first encapsulation structure being removed of the first carrier 301 is turned over, and the first encapsulation structure is attached on the second carrier 302 through adhesive. The adhesive includes a second adhesive layer 402 for fixing the first encapsulation structure and the second carrier 302. Specifically, a surface of the second carrier 302 may be fully coated with a second adhesive layer 402, and the first encapsulation structure is disposed on the second adhesive layer 402. The second adhesive layer 402 may be made of a material easy to peel, so as to peel off the second carrier from the first encapsulation structure, for example, a releasable double-sided adhesive tape.

In this embodiment, when the first carrier 301 is removed, the first pads 1011 on a front side of the wafer is exposed, when the first encapsulation structure is turned over, the first pads 1011 face away from the second carrier 302, and the first pads 1011 on the fixed first encapsulation structure face away from the second carrier 302.

After removing the first carrier to obtain the first encapsulation structure and attaching the first encapsulation structure on the second carrier 302, step S4 is performed, that is, to form a conductive structure, and the conductive structure is in contact with the first pads 1011 to obtain a semiconductor intermediate structure.

FIGS. 26-32 illustrate a forming process of the conductive structure. The conductive structure in this embodiment includes a first redistribution structure. That is, after the first encapsulation structure is attached on the second carrier 302, a first redistribution structure is formed on the first pads 1011. Since the wafer 10 is not cut at this time, relative position between the chips is not changed, and compared with a manner of directly cutting the wafer 10 to form chips and then performing panel-level packaging, expansion of the whole plate is greatly reduced. Therefore, even if the first redistribution structure is manufactured by using the panel-level equipment, the manufacturing precision can be guaranteed.

The first redistribution structure includes a plurality of second lead-out metal pads 601, a plurality of second pads 603, and a plurality of first solder balls 604. The second lead-out metal pads 601 and the second pads 603 may be formed by electrolytic plating, electroless plating, or the like. The second lead-out metal pads 601 and the second pads 603 may be made of a metal material, such as metal copper. The first solder balls 604 may facilitate soldering of the obtained semiconductor structure to other components. The first solder balls 604 may be made of tin.

The manner of forming the first redistribution structure includes:
Step S411: forming second lead-out metal pads 601, where each of the second lead-out metal pads 601 is in contact with a surface of one of the first pads 1011 facing away from the second carrier 302;
Step S412: forming a first insulating layer 701 covering the second lead-out metal pads 601 and an exposed front surface of the wafer;
Step S413: forming first openings 7011, where the first openings 7011 penetrate through the first insulating layer 701, and each of the first openings 7011 exposes one of the second lead-out metal pads 601;
Step S414: forming second pads 603, where each of the second pads 603 is filled in one of the first openings 7011, so that the second pads 603 are in contact with the second lead-out metal pads 601; and
Step S415: forming the first solder balls 604, where each of the first solder balls 604 is in contact with a surface of one of the second pads 603 facing away from the second carrier 302 to obtain a semiconductor intermediate structure, that is, a first semiconductor intermediate structure.

FIG. 26 is an enlarged view of a partial area A of FIG. 25, showing a chip 101 on a wafer, a plurality of first pads 1011 on a front side of the chip, and a passivation layer 1012 covering a portion of each first pad 1011. The chip 101 is preferably a silicon chip, and the material of the passivation layer 1012 may be silicon nitride, silicon oxide or PI (polyimide), but not limited thereto. The passivation layer 1012 is used to protect internal circuits of the chip, and the passivation layer 1012 may be used to determine a size of openings, that is, a size of an exposed surface of each first pad 1011.

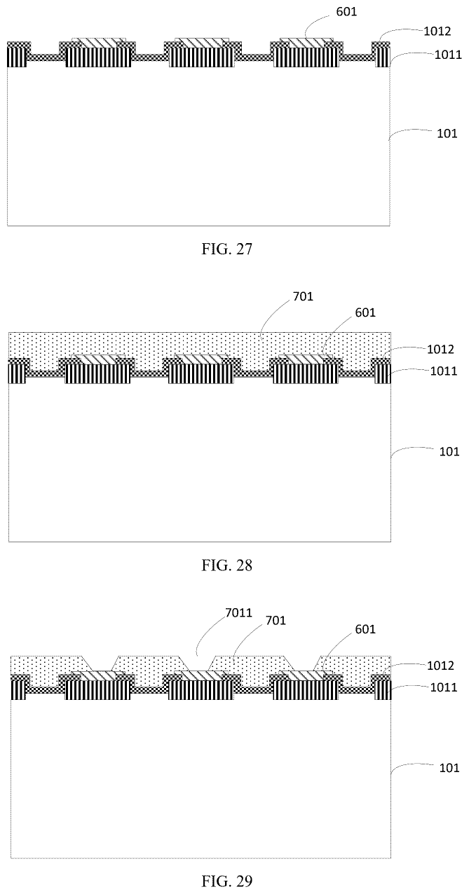

Referring to FIG. 27, step S411 is performed to form a second lead-out metal pad 601 on each first pad 1011 after the first encapsulation structure is attached on the second carrier 302. A number of the second lead-out metal pads 601 is preferably same as a number of the first pads 1011, and each of the first pads 1011 is in contact with one of the second lead-out metal pads 601.

In this embodiment, the second lead-out metal pads 601 are preferably formed by a conventional process for manufacturing an RDL. The second lead-out metal pads 601 can protect the first pads 1011 and avoid a problem of excessive resistance caused by oxidation of the first pads 1011. In a conventional manner, a metal layer (generally nickel and gold) is chemically plated to protect the first pads, so that the problem of excessive resistance can be avoided, but the cost is high. Moreover, the conventional manner cannot completely avoid a problem of damage to the first pads caused by a laser opening process. Compared with the conventional method, the second lead-out metal pads 601 are prepared by adopting an RDL mode, by which the cost is reduced, and the problem that the first pads are damaged due to the laser opening process can be completely avoided.

Referring to FIG. 28, step S412 is performed to form a first insulating layer 701 covering the second lead-out metal pads 601 and an exposed front surface of the wafer. The material of the first insulating layer 701 preferably includes at least one of ABF (Ajinomoto Building Film), PID (Photosensitive Insulation Material) or other insulating films, but not limited thereto. The first insulating layer 701 covers the second lead-out metal pads 601 and rest areas in addition to the second lead-out metal pads 601 (the exposed front surface of the wafer).

Referring to FIG. 29, step S413 is performed to form a plurality of first openings 7011 penetrating through the first insulating layer 701. Each of the first openings 7011 exposes one of the second lead-out metal pads 601. The first openings 7011 are formed by a laser manner or a developing manner, but not limited thereto.

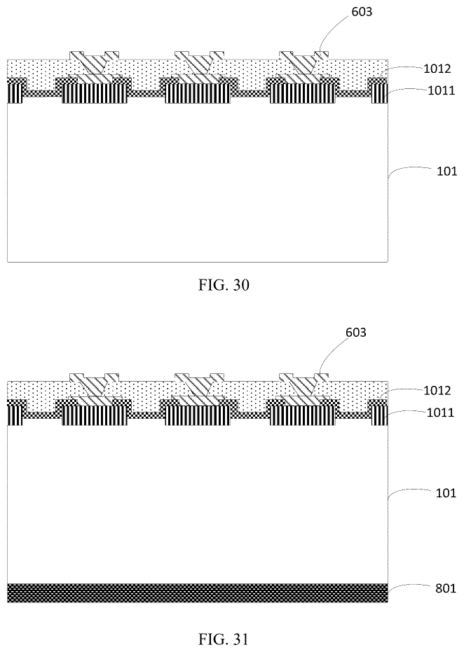

Referring to FIG. 30, in step S414, second pads 603 are formed on the first insulating layer 701, and further, an UBM (Under-Bump Metallization) (i.e., second pads) is preferably manufactured by using an RDL.

Referring to FIG. 31, between step S414 and step S415, the method further includes: removing the second carrier 302, and forming a first protective resin film 801 on an exposed back surface of the wafer 10. Removing manners of the second carrier 302 may be an existing removing manner such as laser peel-off, which will not be specified herein. A material of the first protective resin film 801 includes at least one of a resin film and a build-up film, but is not limited thereto. The build-up film may be another insulating film other than resin.

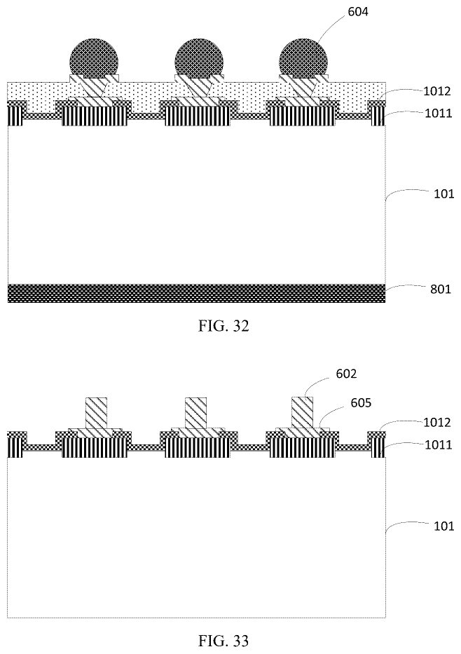

Referring to FIG. 32, step S415 is performed to form first solder balls 604 on the second pads 603 to obtain a semiconductor intermediate structure, where the semiconductor intermediate structure is a first semiconductor intermediate structure. A number of the first solder balls 604 is preferably same as a number of the second pads 603.

After step S415, step S5 may be directly performed to cut the semiconductor intermediate structure to obtain a plurality of sub-structures, which specifically includes: cutting the first semiconductor intermediate structure to obtain a plurality of first sub-structures.

Before step S5, that is, before cutting, the panel-level packaging method may further includes removing the hollowed plate 20, and the removing manner may be an existing removing manner such as laser stripping, which is not specified herein. Since the materials of the wafer and the hollowed plate are different, after the hollowed plate is removed, the intermediate semiconductor structure is more easily cut to obtain the sub-structures.

The first sub-structures are obtained by adopting a processing technology of embedding an encapsulated hollowed plate to carry out encapsulation on a wafer to form a plate, and the wafer-level product structure is processed by adopting this process manner.

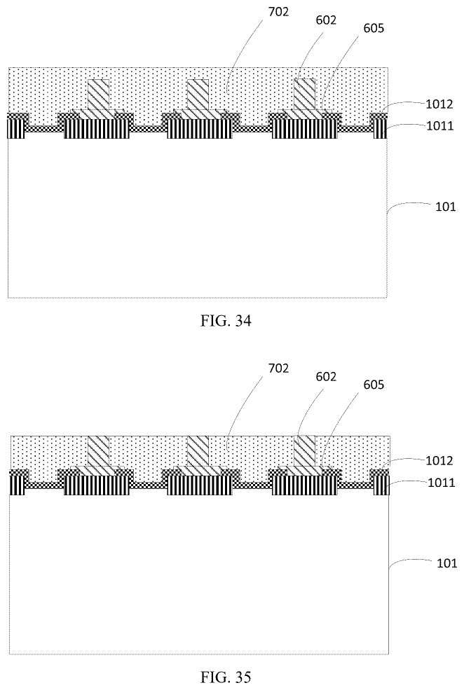

FIGS. 33-35 illustrate a forming process of a second type of the conductive structure. The conductive structure in this embodiment includes a pillar layer. That is, after the first encapsulation structure is attached on the second carrier 302, a pillar layer is formed on the first pads 1011. Since the wafer 10 is not cut at this time, relative position between the chips is not changed, and compared with a manner of directly cutting the wafer 10 to form chips and then performing panel-level packaging, expansion of the whole plate is greatly reduced. Therefore, even if the pillar layer is manufactured by using the panel-level equipment, the manufacturing precision can be guaranteed.

In this embodiment, the pillar layer includes a plurality of first lead-out metal pads 605 and first conductive pillars 602. The first lead-out metal pad 605 and the first conductive pillar 602 are preferably formed by a conventional RDL (Redistribution Layer) process, and may further be formed by electrolytic plating, electroless plating, or the like. The first lead-out metal pads 605 and the first conductive pillars 602 may be made of a metal material, such as metal copper.

The manner for forming the pillar layer includes:
Step S4211: forming the first lead-out metal pads 605, where each of the first lead-out metal pads 605 is in contact with a surface of one of the first pads 1011 facing away from the second carrier 302;
Step S4212: forming the first conductive pillars 602, where each of the first conductive pillars 602 is in contact with a surface of one of the first lead-out metal pads 605 facing away from the second carrier 302.

Referring to FIG. 33, step S4211 is performed, that is, the first lead-out metal pads 605 are formed on the first pads 1011, a number of the first lead-out metal pads 605 is same as a number of the first pads 1011, and each of the first pads 1011 is in contact with one of the first lead-out metal pads 605.

In this embodiment, the first lead-out metal pads 605 are formed by a conventional process for manufacturing an RDL. The first lead-out metal pads 605 can protect the first pads 1011 and avoid a problem of excessive resistance caused by oxidation of the first pads 1011. In a conventional manner, a metal layer (generally nickel and gold) is chemically plated to protect the first pads, so that the problem of excessive resistance can be avoided, but the cost is high. Moreover, the conventional manner cannot completely avoid a problem of damage to the first pads caused by a laser opening process. Compared with the conventional method, the first lead-out metal pads 605 are prepared by adopting an RDL mode, by which the cost is reduced, and the problem that the first pads are damaged due to the laser opening process can be completely avoided.

Still referring to FIG. 33, step S4212 is performed to form the first conductive pillars 602 on the first lead-out metal pads 605. A number of the first conductive pillars 602 is same as a number of the first lead-out metal pads 605, and each of the first conductive pillars 602 is in contact with one of the first lead-out metal pads 605.

Referring to FIGS. 34-35, after step S4212, a manner of forming the pillar layer further includes:
Step S4213: forming a second insulating layer 702 covering the first lead-out metal pads 605, the first conductive pillars 602 and an exposed front surface of the wafer;
Step S4214: removing a portion of the second insulating layer 702 to expose surfaces of the first conductive pillars 602 facing away from the second carrier.

Referring to FIG. 34, step S4213 is performed to form a second insulating layer 702 on the first lead-out metal pads 605, the first conductive pillars 602 and an exposed front surface of the wafer, and the material of the second insulating layer 702 is preferably at least one of ABF, PID or other insulating films, but not limited thereto.

Referring to FIG. 35, step S4214 is performed to remove a portion of the second insulating layer 702. Further, a laser manner, a grinding manner or an exposure and development manner is preferably used to remove a portion of the second insulating layer 702 to expose surfaces of the first conductive pillars 602 facing away from the second carrier 302. Therefore, in this embodiment, after a part of thickness is removed, a surface of the second insulating layer 702 facing away from the second carrier 302 is flush with surfaces of the first conductive pillars 602 facing away from the second carrier 302.

After removing the portion of the second insulating layer 702 to expose the surfaces of the first conductive pillars 602 facing away from the second carrier 302, the panel-level packaging method further includes: removing the second carrier 302 to obtain the semiconductor intermediate structure. The semiconductor intermediate structure is a second semiconductor intermediate structure.

Removing manners of the second carrier 302 may be an existing removing manner such as laser peel-off, which will not be specified herein.

After step S4214, step S5 may be directly performed to cut the semiconductor intermediate structure to obtain a plurality of sub-structures, which specifically includes: cutting the second semiconductor intermediate structure to obtain a plurality of second sub-structures.

Before step S5, that is, before cutting, the panel-level packaging method may further includes removing the hollowed plate 20, and the removing manner may be an existing removing manner such as laser stripping, which is not specified herein. Since the materials of the wafer and the hollowed plate are different, after the hollowed plate is removed, the intermediate semiconductor structure is more easily cut to obtain the sub-structures.

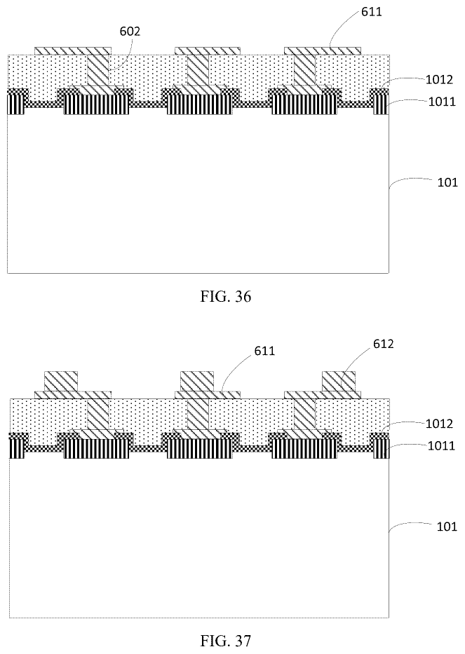

FIGS. 36-37 show a process of forming a third type of the conductive structure. The conductive structure in this embodiment includes a pillar layer and a second redistribution structure. The forming process of the pillar layer in this embodiment may refer to step S4211 to step S4214. That is, after step S4214, a step of forming the second redistribution structure is performed. In this embodiment, the second redistribution structure includes a plurality of first conductive traces 611 and a plurality of second conductive pillars 612.

Referring to FIGS. 36 and 37, a manner of forming the second redistribution structure includes:
Step S4221: forming first conductive traces 611, where each of the first conductive traces 611 is in contact with one of the first conductive pillars 602;
Step S4222: forming second conductive pillars 612, where each of the second conductive pillars 612 is in contact with a surface of one of the first conductive traces 611 facing away from the second carrier.

Referring to FIG. 36, step S4221 is performed to form a plurality of first conductive traces 611 on the second insulating layer 702 and the plurality of first conductive pillars 602. The first conductive traces 611 may be formed by electrolytic plating or electroless plating. A material of the first conductive traces 611 may be a metal material, such as metal copper.

Referring to FIG. 37, step S4222 is performed to form a plurality of second conductive pillars 612 on a surface of the first conductive traces 611 facing away from the second carrier 302. The second conductive pillars 612 may be formed by electrolytic plating, electroless plating, or the like. A material of the second conductive pillar 612 may be a metal material, such as metal copper.

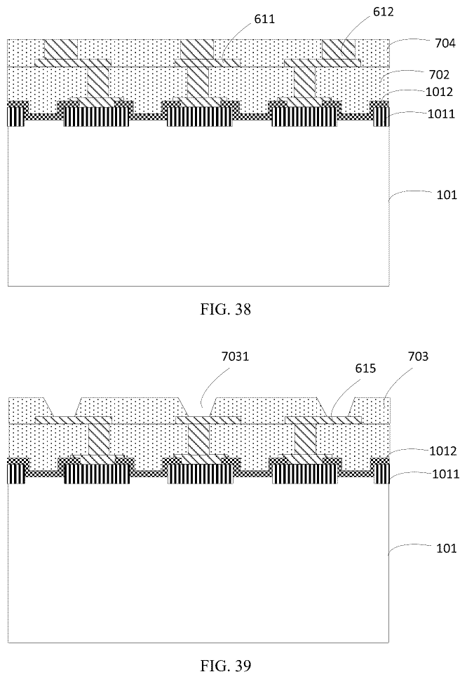

Referring to FIG. 38, after forming a plurality of second conductive pillars 612, and each of the second conductive pillars 612 is in contact with a surface of one of the first conductive traces 611 facing away from the second carrier 302, the manner for forming the second redistribution structure further includes:
Step S4223: forming a fourth insulating layer 704 covering the first conductive traces 611 and the second conductive pillars 612;
Step S4224: removing a portion of the fourth insulating layer 704 to expose the second conductive pillars 612.

Referring to FIG. 38, step S4223 is performed to form a fourth insulating layer 704. A material of the fourth insulating layer 704 preferably includes at least one of ABF, PID or other insulating films, but not limited thereto.

Still referring to FIG. 38, step S4224 is performed to remove a portion of the fourth insulating layer 704. In this embodiment, a laser manner, a grinding manner or an exposure and development manner is preferably used to remove a portion of the fourth insulating layer 704 to expose surfaces of the second conductive pillars 612 facing away from the second carrier 302. Therefore, in this embodiment, after a part of thickness is removed, a surface of the fourth insulating layer 704 facing away from the second carrier 302 is flush with surfaces of the second conductive pillars 602 facing away from the second carrier 302.

After removing a portion of the fourth insulating layer 704, the panel-level packaging method further includes removing the second carrier 302 and the hollowed plate 20 to obtain the semiconductor intermediate structure. Removing manners of the second carrier 302 may be an existing removing manner such as laser peel-off, which will not be specified herein. The semiconductor intermediate structure is a third semiconductor intermediate structure.

After removing the second carrier 302 and the hollowed plate 20, step S5 may be directly performed to cut the third semiconductor intermediate structure to obtain a plurality of third sub-structures.

FIGS. 39-41 illustrate a process of forming a fourth type of the conductive structure. The conductive structure in this embodiment includes a pillar layer and a third redistribution structure. The forming process of the pillar layer in this embodiment may refer to step S4211 to step S4214. That is, after step S4214, a step of forming the third redistribution structure is performed. In this embodiment, the third redistribution structure includes a plurality of second conductive traces 615, a plurality of third pads 613, and a plurality of second solder balls 614, and the third redistribution structure is in contact with surfaces of the first conductive pillars 602 facing away from the second carrier 302.

The manner of forming the third redistribution structure includes:
Step S4231: forming the second conductive traces 615, where each of the second conductive traces 615 is in contact with one of the first conductive pillars 602;
Step S4232: forming a third insulating layer 703 covering the second insulating layer 702 and the second conductive traces 615;
Step S4233: forming second openings 7031, where the second openings 7031 penetrate through the third insulating layer 703, and each of the second openings 7031 exposes one of the second conductive traces 615;
Step S4234: forming third pads 613, where each of the third pads 613 is in contact with one of the second conductive traces 615;
Step S4235: forming second solder balls 614, where each of the second solder balls 614 is in contact with a surface of one of the third pads 613 facing away from the second carrier 302 to obtain a third semiconductor intermediate structure.

Referring to FIG. 39, step S4231 is performed to form a plurality of second conductive traces 615 on the second insulating layer 702. The second conductive traces 615 may be formed by electrolytic plating or electroless plating. A material of the second conductive traces 615 may be a metal material, such as metal copper.

Still referring to FIG. 39, step S4232 is performed to form a third insulating layer 703. A material of the third insulating layer 703 preferably includes at least one of ABF, PID or other insulating films, but not limited thereto.

Still referring to FIG. 39, step S4233 is performed to form a plurality of second openings 7031 on the third insulating layer 703. The second openings 7031 are formed by a laser manner or a developing manner, but not limited thereto. Each of the second openings 7031 exposes one of the second conductive traces 615.

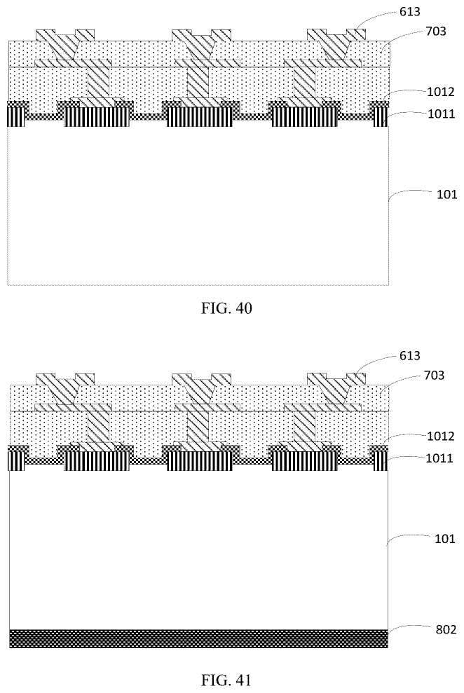

Referring to FIG. 40, step S4234 is performed to form a plurality of third pads 613 on the third insulating layer 703, and each of the third pads 613 further fills into one of the second openings 7031, so that each of the third pads 613 is in contact with one of the second conductive traces 615. The third pads 612 may be formed by electrolytic plating, electroless plating, or the like. The third pads 613 may be made of a metal material, such as metal copper.

Referring to FIG. 41, before forming the second solder balls 614, the method further includes: peeling off the second carrier 302, and forming a second protective resin film 802 on the back surface of the wafer 10. The second protective resin film 802 is preferably made of same material as the first protective resin film 801.

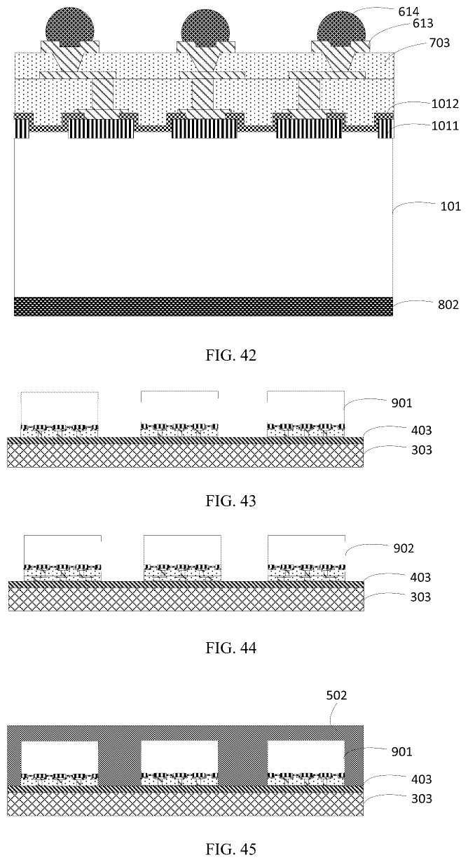

Referring to FIG. 42, step S4235 is performed to form the second solder balls 614 on the third pads 613 to obtain a semiconductor intermediate structure, where the semiconductor intermediate structure is a fourth semiconductor intermediate structure. A number of the second solder balls 614 is preferably same as a number of the third solder pads 613.

After forming the plurality of second solder balls 614, step S5 may be directly performed to cut the semiconductor intermediate structure to obtain a plurality of sub-structures, specifically the method includes: cutting the fourth semiconductor intermediate structure to obtain a plurality of fourth sub-structures. The hollowed plate 20 and the second carrier 302 are preferably removed before cutting the semiconductor intermediate structure, because materials of the wafer 10 and the hollowed plate 20 are different, after the removal, the intermediate structure is more easily cut to obtain the sub-structures.

The fourth sub-structures are obtained by adopting a processing technology of embedding an encapsulated hollowed plate to carry out encapsulation on a wafer to form a plate, and the wafer-level product structure is processed by adopting this process manner.

Referring to FIGS. 43-54, after step S5, the panel-level packaging method of the semiconductor structure may further include:
Step S6: providing a third carrier 303 and selecting some of the sub-structures, where the conductive structure is located in a front surface of each of the sub-structures, the sub-structures are attached on the third carrier 303, and the conductive structure faces toward the third carrier 303;
Step S7: forming a second encapsulation layer 502 covering the sub-structures;
Step S8: removing the third carrier 303 to obtain a second encapsulation structure, and attaching the second encapsulation structure on a fourth carrier 304, where the conductive structure faces away from the fourth carrier;
Step S9: forming a fourth redistribution structure in contact with the conductive structure to obtain a semiconductor package structure, and cutting the semiconductor package structure to obtain sub-package structures.

Referring to FIGS. 43 and 44, step S6 is performed to provide a third carrier 303 and select a plurality of sub-structures, and the sub-structures are attached on the third carrier 303. The third carrier 303 is preferably a panel-level carrier, and the panel-level carrier refers to a large carrier used in a panel-level packaging process. The sub-structures may be the second sub-structures 901 and/or the third sub-structures 902 obtained in the above embodiments. In this embodiment, the sub-structures can be fixed on the third carrier 303 by pressing or by adhesive. For example, adhesive may be disposed between the third carrier 303 and the second sub-structures 901 or the third sub-structures 902 to fix the third carrier 303 and the second sub-structures 901 or the third sub-structures 902. Specifically, a surface may be fully coated on a surface of the third carrier 303, and the second sub-structures 901 or the third sub-structures 902 are placed on the adhesive. The adhesive may be made of a material easy to peel, so as to peel the third carrier from the second sub-structures 901 or the third sub-structures 902, for example, a releasable double-sided tape. For example, in FIGS. 43 and 44, the second sub-structures 901 or the third sub-structures 902 are fixed on the third carrier 303 by adhesive, that is, a third adhesive layer 403.

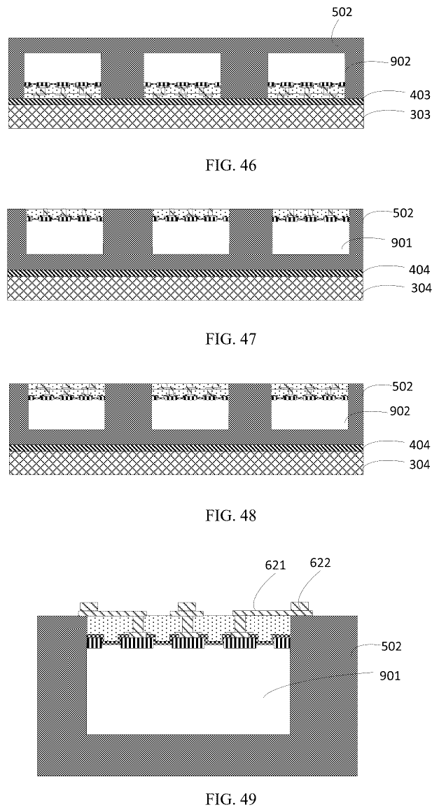

Referring to FIGS. 45 and 46, step S7 is performed to form a second encapsulation layer 502. The second sub-structures 901 or the third sub-structures 902 are encapsulated to form the second encapsulation layer 502. The second encapsulation layer 502 covers side surfaces and back surfaces of the second sub-structures 901 or the third sub-structures 902. As shown in FIG. 45, the second encapsulation layer 502 covers side surfaces of each second sub-structure 901 and a back surface of each second sub-structure 901. In this embodiment, the second encapsulation layer 502 further covers a surface of the third carrier 303 facing the second sub-structures 901.

A material of the second encapsulation layer 502 may be polymer, resin, resin composite material or polymer composite material. The second encapsulation layer 502 may be formed by lamination, injection molding, compression molding or transfer molding.

Referring to FIGS. 47 and 48, step S8 is performed to remove the third carrier 303 to obtain a second encapsulation structure, and attaching the second encapsulation structure on a fourth carrier 304, where the conductive structure faces away from the fourth carrier.

Removing manners of the third carrier 303 may be an existing removing manner such as laser peel-off, which will not be specified herein. The fourth carrier 304 is preferably a panel-level carrier. In this embodiment, the second encapsulation structure being removed of the third carrier 303 is turned over, and the second encapsulation structure is attached on the fourth carrier 304 through adhesive. The adhesive is a fourth adhesive layer 404 for fixing the second encapsulation structure and the fourth carrier 304. Specifically, a surface of the fourth carrier 304 may be fully coated with the fourth adhesive layer 404, and the second encapsulation structure is disposed on the fourth adhesive layer 404. The fourth adhesive layer 404 may be made of a material easy to peel off, so as to peel off the fourth carrier 304 and the second encapsulation structure, for example, a releasable double-sided adhesive tape.

In this embodiment, when the third carrier 303 is removed, the conductive structure on the front surface of the sub-structure is exposed, and when the second encapsulation structure is turned over, the conductive structure faces away from the fourth carrier 304, and the conductive structure on the fixed second encapsulation structure faces away from the fourth carrier 304. Moreover, if the residual adhesive exists after removing the third carrier 303, the residual adhesive may be removed by grinding. In conventional panel-level processing manners, wiring is usually led out by openings, and residual adhesive cannot be removed by grinding since grinding may cause block of openings. However, the present disclosure can use a grinding manner to solve the problem of scrapping caused by the double-sided adhesive (adhesive layer) in the processing.

Referring to FIGS. 49-54, step S9 is performed to form a fourth redistribution structure, and the fourth redistribution structure is in contact with the conductive structure.

The fourth redistribution structure includes a plurality of third conductive traces 621, a plurality of third conductive pillars 622, and a plurality of third solder balls 623. The fourth redistribution structure is in contact with the conductive structure, and a manner of forming the fourth redistribution structure includes:
Step S91: forming third conductive traces 621, where each of the third conductive traces 621 is in contact with the conductive structure;
Step S92: forming third conductive pillars, where each of the third conductive pillars 622 is in contact with a surface of one of the third conductive traces 621 facing away from the fourth carrier 304;
Step S93: forming a fifth insulating layer 705 covering the third conductive traces 621, the third conductive pillars 622, and front surfaces of the sub-structures;
Step S94: removing a portion of the fifth insulating layer 705 to expose the third conductive pillars 622; and
Step S95: forming the third solder balls 623, where each of the third solder balls 623 is in contact with a surface of one of the third conductive pillars 622 facing away from the fourth carrier 304.

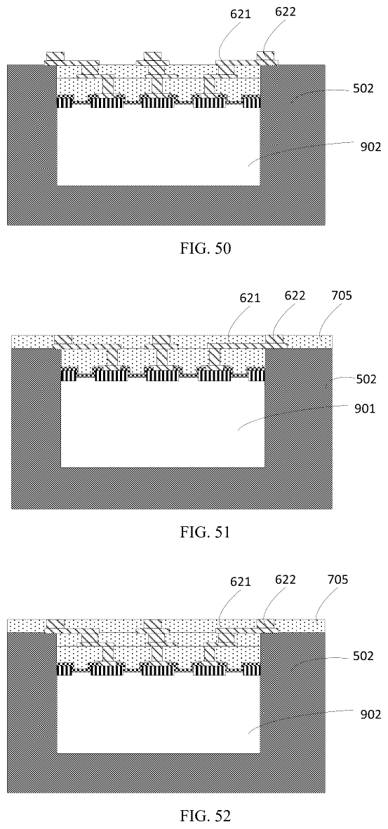

Referring to FIGS. 49 and 50, step S91 is performed to form a plurality of third conductive traces 621 on a front surface of the sub-structure. The third conductive traces 621 may be formed by electrolytic plating, electroless plating, or the like. A material of the third conductive traces 621 may be a metal material, such as metal copper.

Still referring to FIGS. 49 and 50, step S92 is performed to form the third conductive pillars 622 on the third conductive traces 621, and each of the third conductive pillars 622 is in contact with one of the third conductive traces 621. The third conductive pillar 622 may be formed by electrolytic plating, electroless plating, or the like. The third conductive pillar 622 may be made of a metal material, such as copper.

Referring to FIGS. 51-52, steps S93 and S94 are sequentially performed to form a fifth insulating layer 705, and remove a portion of the fifth insulating layer 705. The material of the fifth insulating layer 705 is preferably at least one of ABF, PID or other insulating films, but not limited thereto. In this embodiment, a laser manner, a grinding manner or an exposure and development manner is preferably used to remove a portion of the fifth insulating layer 705 to expose surfaces of the third conductive pillars 622 facing away from the fourth carrier 304. Therefore, in this embodiment, after a part of thickness is removed, a surface of the fifth insulating layer 705 facing away from the fourth carrier 304 is flush with surfaces of the third conductive pillars 622 facing away from the fourth carrier 304.

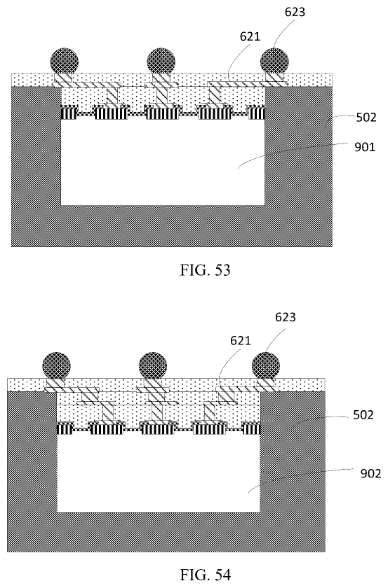

Referring to FIGS. 53 and 54, step S95 is performed to form the third solder balls 623 on the third conductive pillars 622 to obtain a semiconductor package structure. A number of the third solder balls 623 is preferably same as a number of the third conductive pillars 622.

Before step S95, the method may further include: removing the fourth carrier 304.

After removing the fourth carrier 304, the method may further include: forming a protective resin film on a back surface of the second encapsulation structure. Removing manners of the fourth carrier 304 may be an existing removing manner such as laser peel-off, which will not be specified herein.

Lastly, the semiconductor encapsulation structure is cut to obtain sub-package structures. The sub-packaging structures are obtained by adopting a processing technology of embedding an encapsulated hollowed plate to carry out encapsulation on a wafer to form a plate, and the wafer-level product structure is processed by adopting this process manner.

As can be seen, the present disclosure provides a panel-level packaging method for a semiconductor structure, which adopts a hollowed plate to encapsulate and reconstruct a wafer into panel-level, and then perform panel-level packaging to realize wafer-level packaging, so as to expand a processing range of the panel-level packaging equipment. According to the present disclosure, wafer-level packaging can be realized under the condition that only panel-level packaging equipment is adopted, namely, wafer-level packaging processing is carried out on the panel-level packaging equipment, high cost of wafer-level packaging equipment is avoided, and product structure processing of panel-level packaging processing after wafer processing being carried out on the panel-level packaging equipment is also realized. In a condition of high precision requirement, the present disclosure can realize, by adopting the panel-level packaging technology, the redistribution that needs to be performed directly on the wafer and then the panel-level packaging to meet such precision requirement, thus the present disclosure adopts the panel-level device to perform wafer-level packaging processing without using the wafer-level processing device, which is less costly.

According to the present disclosure, before the wafer with aluminum pads is subjected to panel-level packaging, the panel-level equipment can process a layer of protective metal on the aluminum pads, so that a problem of overhigh resistance caused by aluminum pad oxidation is avoided. In addition, the panel-level packaging method for the semiconductor structure can solve a problem of scrapping caused by residual adhesive and the like in the processing process.

In addition, it should be understood that although the present disclosure has been described above with reference to preferred embodiments, the above embodiments are not intended to limit the present disclosure. For any person skilled in the art, many possible variations and modifications may be made to the technical solutions of the present disclosure by using the technical contents disclosed above, or modified into equivalent embodiments of equivalent variations without departing from the scope of the technical solutions of the present disclosure. Therefore, any simple modification, equivalent change and modification made to the above embodiments according to the technical essence of the present disclosure without departing from the content of the technical solution of the present disclosure still fall within the protection scope of the technical solution of the present disclosure.

It should also be understood that the disclosure is not limited to the specific methods, compounds, materials, manufacturing techniques, uses, and applications described herein, which may vary. It should also be understood that the terminology described herein is merely used to describe particular embodiments and is not intended to limit the scope of the present disclosure. It must be noted that the singular forms “a,” “an,” and “the” as used herein and in the appended claims include plural references unless the context clearly indicates otherwise. Thus, for example, reference to “a step” means reference to one or more steps and may include secondary steps. All conjunctions used should be understood in the broadest sense. Thus, the word “or” should be understood to be provided with the definition of a logical “or” rather than the definition of a logical “exclusive OR” unless the context clearly indicates to the contrary. The structures described herein will be understood to also refer to the functional equivalents of the structures. Language that may be interpreted as approximate should be understood unless the context clearly indicates to the contrary.

1. A panel-level packaging method for a semiconductor structure, comprising:
providing wafers, a hollowed plate and a first carrier, wherein the hollowed plate comprises hollowed portions, a size of each of the hollowed portions is larger than a size of each of the wafers, the hollowed plate is attached to the first carrier, a front surface of the wafer is provided with first pads, the wafers are aligned to the hollowed portions and are attached to the first carrier, and the first pads face toward the first carrier;
forming a first encapsulation layer, wherein the first encapsulation layer covers at least side surfaces of the wafers;
removing the first carrier to obtain a first encapsulation structure, and attaching the first encapsulation structure on a second carrier, wherein the first pads face away from the second carrier;
forming a conductive structure in contact with the first pads to obtain a semiconductor intermediate structure; and
cutting the semiconductor intermediate structure to obtain sub-structures.

2. The panel-level packaging method for the semiconductor structure according to claim 1, wherein the size of each of the hollowed portions is 1 mm to 5 mm larger than the size of each of the wafers.

3. The panel-level packaging method for the semiconductor structure according to claim 1, wherein the conductive structure comprises a pillar layer, the pillar layer comprises first lead-out metal pads and first conductive pillars, and forming the pillar layer comprises:
forming the first lead-out metal pads, wherein each of the first lead-out metal pads is in contact with a surface of one of the first pads facing away from the second carrier;
forming the first conductive pillars, wherein each of the first conductive pillars is in contact with a surface of one of the first lead-out metal pads facing away from the second carrier.

4. The panel-level packaging method for the semiconductor structure according to claim 3, wherein after forming the first conductive pillars, wherein each of the first conductive pillars is in contact with the surface of one of the first lead-out metal pads facing away from the second carrier, forming the pillar layer further comprises:
forming a second insulating layer covering the first lead-out metal pads, the first conductive pillars and an exposed front surface of the wafer; and
removing a portion of the second insulating layer to expose surfaces of the first conductive pillars facing away from the second carrier.

5. The panel-level packaging method for the semiconductor structure according to claim 4, wherein after removing the portion of the second insulating layer to expose the surfaces of the first conductive pillars facing away from the second carrier, the panel-level packaging method further comprises: removing the second carrier and the hollowed plate to obtain the semiconductor intermediate structure.

6. The panel-level packaging method for the semiconductor structure according to claim 4, wherein the conductive structure further comprises a second redistribution structure, the second redistribution structure comprises first conductive traces and second conductive pillars, and forming the second redistribution structure comprises:
forming the first conductive traces, wherein each of the first conductive traces is in contact with one of the first conductive pillars;
forming the second conductive pillars, wherein each of the second conductive pillars is in contact with a surface of one of the first conductive traces facing away from the second carrier.

7. The panel-level packaging method for the semiconductor structure according to claim 6, wherein after forming the second conductive pillars, wherein each of the second conductive pillars is in contact with the surface of one of the first conductive traces facing away from the second carrier, forming the second redistribution structure further comprises:
forming a fourth insulating layer covering the first conductive traces and the second conductive pillars; and
removing a portion of the fourth insulating layer to expose the second conductive pillars.

8. The panel-level packaging method for the semiconductor structure according to claim 7, wherein after removing the portion of the fourth insulating layer to expose the second conductive pillars, the panel-level packaging method further comprises: removing the second carrier and the hollowed plate to obtain the semiconductor intermediate structure.

9. The panel-level packaging method for the semiconductor structure according to claim 1, wherein after cutting the semiconductor intermediate structure to obtain the sub-structures, the panel-level packaging method for the semiconductor structure further comprises:
providing a third carrier and selecting some of the sub-structures, wherein the conductive structure is located in a front surface of each of the selected sub-structures, the selected sub-structures are attached on the third carrier, and the conductive structure faces toward the third carrier;
forming a second encapsulation layer covering the selected sub-structures;
removing the third carrier to obtain a second encapsulation structure, and attaching the second encapsulation structure on a fourth carrier, wherein the conductive structure faces away from the fourth carrier; and
forming a fourth redistribution structure in contact with the conductive structure to obtain a semiconductor package structure, and cutting the semiconductor package structure to obtain sub-package structures.

10. The panel-level packaging method for the semiconductor structure according to claim 9, wherein the fourth redistribution structure comprises third conductive traces, third conductive pillars, and third solder balls, and forming the fourth redistribution structure comprises:
forming the third conductive traces, wherein each of the third conductive traces is in contact with the conductive structure;
forming the third conductive pillars, wherein each of the third conductive pillars is in contact with a surface of one of the third conductive traces facing away from the fourth carrier;
forming a fifth insulating layer covering the third conductive traces, the third conductive pillars, and front surfaces of the selected sub-structures;
removing a portion of the fifth insulating layer to expose the third conductive pillars; and
forming the third solder balls, wherein each of the third solder balls is in contact with a surface of one of the third conductive pillars facing away from the fourth carrier.

11. The panel-level packaging method for the semiconductor structure according to claim 4, wherein the conductive structure further comprises a third redistribution structure, the third redistribution structure comprises second conductive traces, third pads and second solder balls, and forming the third redistribution structure comprises:
forming the second conductive traces, wherein each of the second conductive traces is in contact with one of the first conductive pillars;
forming a third insulating layer covering the second insulating layer and the second conductive traces;
forming second openings, wherein the second openings penetrate through the third insulating layer, and each of the second openings exposes one of the second conductive traces;
forming the third pads, wherein each of the third pads is in contact with one of the second conductive traces; and
forming the second solder balls, wherein each of the second solder balls is in contact with a surface of one of the third pads facing away from the second carrier to obtain the semiconductor intermediate structure.

12. The panel-level packaging method for the semiconductor structure according to claim 1, wherein the conductive structure comprises a first redistribution structure, the first redistribution structure comprises second lead-out metal pads, second pads and first solder balls, and forming the first redistribution structure comprises:
forming the second lead-out metal pads, wherein each of the second lead-out metal pads is in contact with a surface of one of the first pads facing away from the second carrier;
forming a first insulating layer covering the second lead-out metal pads and an exposed front surface of the wafer;
forming first openings, wherein the first openings penetrate through the first insulating layer, and each of the first openings exposes one of the second lead-out metal pads;
forming the second pads, wherein each of the second pads is filled in one of the first openings, so that the second pads are in contact with the second lead-out metal pads; and
forming the first solder balls, wherein each of the first solder balls is in contact with a surface of one of the second pads facing away from the second carrier to obtain the semiconductor intermediate structure.
